(19) United States
(12) Patent Application Publication
(10) Pub. No.: US 2015/0243534 A1
(43) Pub. Date: Aug. 27, 2015

(54) Copper Wire Bonding Apparatus Using A Purge Gas to Enhance Ball Bond Reliability

(71) Applicant: LSI Corporation, San Jose, CA (US)

(72) Inventors: John W. Osenbach, Kutztown, PA (US); BeiQi Wang, Shanghai (CN); Steven Lowell Haehn, Fort Collins, CO (US); Mintra Veeranarong, Bangkok (TH)

(73) Assignee: LSI Corporation, San Jose, CA (US)

(21) Appl. No.: 14/252,851

(22) Filed: Apr. 15, 2014

Related U.S. Application Data
(60) Provisional application No. 61/944,663, filed on Feb. 26, 2014.

(51) Int. Cl. H01L 21/67; H01L 21/02; H01L 23/00; H01L 21/687

(52) U.S. Cl. CPC H01L 21/67138; H01L 21/67098; H01L 21/68721; H01L 21/02052; H01L 24/83

(57) ABSTRACT

A bonding apparatus and method of bonding copper bond wires to bond pads on an integrated circuit devices attached to a substrate. A heater block heats the devices and substrate prior to and during wire bonding. A clamp presses the substrate down onto the heater block during wire bonding and thereby forms a region of the substrate isolated from the remainder of the substrate. A bonder head creates ball bonds as it attaches one end of the bond wires to the bond pads on the devices within the isolated region. The bonder head also attaches the other end of the bond wires to substrate pads adjacent the devices being wire bonded. To prevent corrosion of the ball bonds, a gas source floods the substrate and the attached devices that have not yet wire bonded with a purge gas while the heater block heats the substrate and the attached devices.

### CROSS-REFERENCE TO RELATED APPLICATIONS

This application claims the benefit of the filing date of U.S. provisional patent application No. 61/944,663 filed 26 Feb. 2014 as attorney docket no. L13-14124US1, the teachings of which are incorporated herein by reference.

### BACKGROUND OF THE INVENTION

1. Field of the Invention

The present invention relates to semiconductor packaging technology generally and, more specifically, to wire bonding of integrated circuit devices to a substrate using copper bond wires.

2. Description of the Related Art

Wire bonding is a widely used technique for electrically interconnecting a semiconductor device or “chip” to conductors on an organic-based substrate, such as a thin (less than one millimeter thick) glass-epoxy board. Traditionally, gold bond wires were used to do the interconnection between a die pad, typically aluminum, on the device and a nickel/gold-plated copper substrate pad on the substrate. However, due to the high cost of gold, copper and palladium-coated copper bond wires have become popular. The copper bond wires are bonded between bond pads on the device and substrate pads on the substrate in a wire bonder machine using conventional ultrasonic bonding techniques.

Because copper is less noble and therefore more reactive than gold, care must be employed to prevent contamination of the copper wire and pads so that a reliable bond can be made. However, even with controlled environments and extensive cleaning techniques to prevent contamination, it is clear that copper wire bonded devices experience a slightly elevated field failure rate relative to gold wire bonded devices. This failure rate might be one reason copper bond wire technology has not been readily adopted in high-reliability applications such as in the automotive industry.

Moreover, the temperature cycling, humidity (with and without an applied bias), thermal exposure, and other stresses can lead to the formation of interface defects including cracks that can eventually cause separation of the copper bond wire and a pad, possibly resulting in a functional failure of the wire bonded device. Thus, it is desirable to understand the mechanism causing the failures and provide a technique to address those failures to increase the reliability of copper bond wire technology and, concomitantly, a more reliable wire bonded device.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Described embodiments include a wire bonder having a heater block configured to heat a substrate and devices attached to a major surface of the substrate, a clamp configured to press the substrate down onto the heater block and thereby isolating a region of the substrate and devices attached thereto from a remainder of the substrate and devices, a bonder head operable within the isolated region and configured to attach bond wires from bond pads on the devices to substrate pads on the major surface and adjacent to the device being wire bonded, and a gas source configured to flood a portion of the substrate and the devices attached thereto with a purge gas while the substrate and attached devices are being heated by the heater, the portion being apart from the substrate and the devices in the isolated region.

### BRIEF DESCRIPTION OF THE DRAWINGS

Other embodiments of the present invention will become more fully apparent from the following detailed description, the appended claims, and the accompanying drawings in which like reference numerals identify similar or identical elements. The drawings are not to scale.

FIG. 1 is a plan view of an exemplary wire bonder with a substrate and attached devices in process of being wire bonded and including a gas distribution system in accordance with an embodiment of the invention; and

FIG. 2 is a cross-section of the structure of FIG. 1, also illustrating a wire bonder head including a capillary, bond wire, and a gas distribution system in accordance with an embodiment of the invention; and

FIG. 3 is a flowchart illustrating an exemplary process to package an integrated circuit device and a substrate using copper wire bonding in accordance with an embodiment of the invention;

### DETAILED DESCRIPTION

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation”.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

It should be understood that the steps of the exemplary methods set forth herein are not necessarily required to be performed in the order described, and the order of the steps of such methods should be understood to be merely exemplary. Likewise, additional steps might be included in such methods, and certain steps might be omitted or combined, in methods consistent with various embodiments of the present invention.

Also for purposes of this description, the terms “couple”, “coupling”, “coupled”, “connect”, “connecting”, or “connected” refer to any manner known in the art or later developed in which energy is allowed to be transferred between two or more elements, and the interposition of one or more additional elements is contemplated, although not required. Conversely, the terms “directly coupled”, “directly connected”, etc., imply the absence of such additional elements.

The present invention will be described herein in the context of illustrative embodiments of an apparatus and process to wire bond an integrated circuit device to a substrate by wire bonding bond pads on the integrated circuit device to substrate pads on the substrate using copper bond wire. While the device and substrate are heated just prior to the step of wire bonding, an inert or low moisture content purge gas is used to flush the substrate to prevent build up of chlorine or other reactive gases during wire bonding. Here, low moisture content refers to the dew point of the purge gas and is desirably less than 10° C., and preferably less than −20° C.

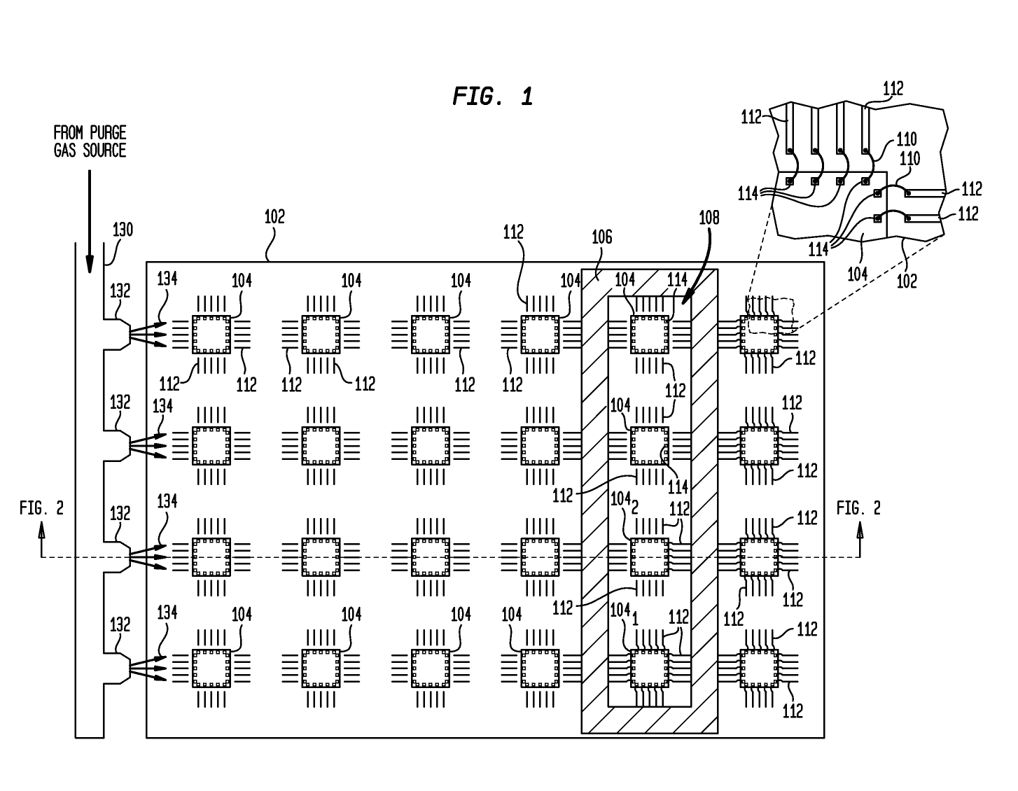

FIG. 1 is a plan view of a portion of an exemplary wire bonder 100. A substrate 102 has twenty-four integrated circuit devices 104 attached to the substrate and arranged in a four-by-six array, although other arrangements might be used instead including a single device on a single substrate. The devices 104 are attached to die paddles (not shown) on the substrate using an adhesive such as conductive epoxy. A clamp 106, having walls that serve to isolate a region or volume 108 from the rest of the substrate 102, holds the substrate in place during wire bonding. In an alternative embodiment, the clamp 106 might be two separate halves with an opening between the clamp halves at the top or bottom of FIG. 1 when the clamp is pressing down on the substrate. A bonding head (not shown) is positioned and operable within the region 108 to wire bond the bond pads 114 to substrate pads 112. An enlargement of a portion of a device 104 and substrate 102 is shown illustrating the bond pads 114, substrate pads 112, and bond wires 110. The devices 104 on the right side of the drawing illustrate completed devices with the required bond wires 110 going from bond pads 114 on the devices 104 to substrate pads 112 on the substrate 102. Within the region 108, the bottom-most device 104₁ is shown completed but the next device 104₂ is in process where only one set of completed wire bonds 110 is shown.

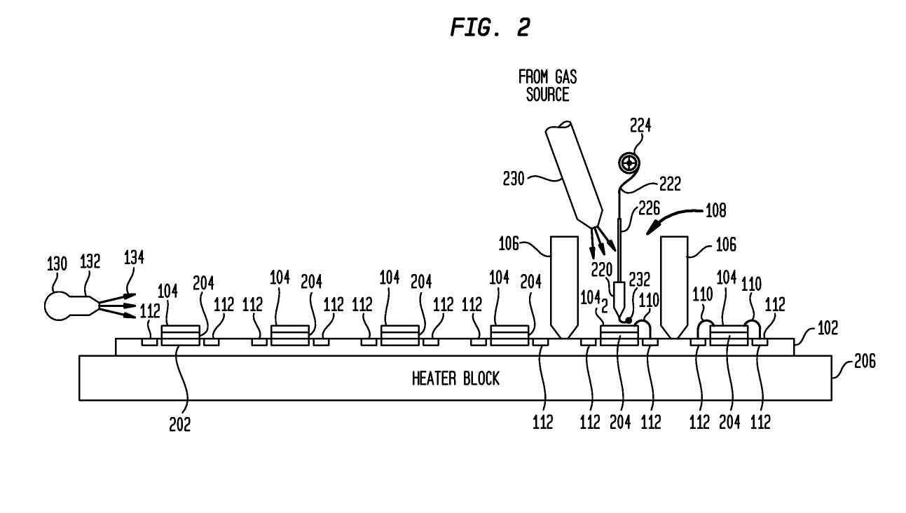

For simplicity, in the view in FIG. 1 the actual bonder head, wire capillary, and bond wire source are not shown. Also not shown in this view is a heater underneath the substrate 102 that is used to heat the substrate and devices prior to and during wire bonding. These are shown in FIG. 2.

The devices 104 might be formed from silicon, gallium arsenide, indium phosphide, or another semiconductor material suitable for the desired function of the devices 104, or a combination thereof. The substrate 102 might be formed from a glass-epoxy (commonly known as FR-4), polytetrafluoroethylene (PTFE), polyimide, ceramics, silicon, glass, another insulating material suitable as a substrate, or a combination of these materials. Typically, the thickness of the substrate 102 is less than two millimeter and might be as thin as 50 microns (μm). The bond pads 114 are typically made of copper or aluminum and the substrate pads are typically made of copper. The bond wire is a copper or palladium-covered copper wire having a diameter ranging from approximately 10 to 250 μm or so.

FIG. 2 is a cross-section along a line demarked in FIG. 1 and illustrates a cross-section of the substrate 102, devices 104, substrate pads 112, die paddles 202, adhesive 204, and heater block 206. Within the walls of the clamp 106 is a conceptualized bonder head 220 with a supply of bond wire 222 fed from a spool of bond wire 224 to the head 220 through a capillary 226. The device 104 on the right side of the drawing illustrates a completed device with bond wires 110 going from bond pads (not shown) on the device 104 to substrate pads 112. Within the region 108, the device 104₂, corresponding to the device 104₂ in FIG. 1, is in process with only one completed wire bond 110 shown. A gas, such as nitrogen, forming gas, or condensed dry air (CDA), is supplied to the region 108 by a nozzle 230. This gas is used to suppress oxidation or corrosion of the bond wire during bonding. It is understood that in an alternative embodiment the gas is instead supplied to the region 108 by the head 220. Because of the walls formed by the clamp 106, the supplied gas remains within the walls and keeps out contaminants as the gas floods the region 108. However, the gas remains localized to the region 108.

Briefly and as well understood in the art, during the actual wire bonding the substrate is held into position using the walled clamp 106 that presses the substrate down onto the heater block 206. Due to different coefficients of thermal expansion (CTE) of the substrate and devices, the heater block 206 elevates the temperature of the substrate and devices to a known temperature so that the bond pads and the substrate pads are in predetermined positions for the bonder head 220 to contact. The bonder head 220 operates within the walls of the clamp 106 (region 108) to wire bond the bond pads 114 on the devices 104 to substrate pads 112 on the substrate 102. The bonder wire 222 protruding from the bonder head has a ball 232 formed on the end of the wire by using an electrical spark to melt the end of the bond wire. Then a bonder head is positioned over a device 104 and the ball 232 on the end of the bond wire is brought into contact with a bond pad 114 on the surface of the device. The head vibrates ultrasonically to form a ball bond that attaches the ball 232 on the bond wire to the bond pad. Then head 220 moves over to a respective substrate pad 112 on the substrate 102 and the bond wire is similarly attached to the respective substrate pad and then the wire is cut to complete the wire bond. Once a device as been wire bonded to the substrate, the head 220 moves to the next device within the region 108 and the wire bonding process begins again. Once all the bond pads on the devices in region 108 is wire bonded, the clamp 106 is lifted, the substrate 102 is indexed to the right to move the next set of devices to be wire bonded into region 108, the clamp 106 lowered, and the above process to wire bond the devices repeats until all the devices on the substrate are wire bonded.

An analysis of a failed ball bond formed using the above-described process with the bonder shown in FIGS. 1 and 2 was done. The edge of the ball was found to have a porous copper “film” with a significant concentration of chlorine therein. A scanning electron microscope image of the copper ball bonded to the aluminum bond pad showed intermittent intermetallic compound (IMC) formation between the ball and bond pad, and there were gaps between the ball and well-formed IMC. A crack was observed running through the interface between the ball and the IMC. In addition, traces of chlorine were found at the ball bond-pad interface and some portions of the interface have what appears to be corroded IMC.

While not wanting to be held to any particular theory, it is believed that halogens, such as chlorine, and other reactive species evaporate from substrate, die attach adhesive, chamber walls, tooling, etc. contaminate the exposed bond pads and substrate pads while waiting for wire bonding. This is contamination is especially pernicious while the substrate 102 and devices 104 are heated by heater block 206. It was discovered that those devices waiting the longest for bonding in the bonder 100 had the highest likelihood of ball bond failure. Because the ball 232 is formed via arc melting the copper bond wire to a temperature greater than the melting temperature of copper (˜1085° C.), it is believed that the gas stream from nozzle 230 prevents any gas contaminants from interacting with the copper bond wire during ball formation. However, when the copper ball 232 cools from the melting temperature to room temperature as the head 220 is translated toward a bond pad, if the gas stream does not fully flush the region 108 of the contaminant gases, then at temperatures greater than approximately 150-200° C. the copper ball and contaminants might react form Cu₃Cl₃ gas phases which might tend to stay in and around the ball 232. Even if the region 108 is fully purged, contaminants on the surface of the bond pads might cause the Cu₃Cl₃ for form during bonding to the bond pads. Moreover, when ball temperature falls below 150-200° C., then the Cu₃Cl₃ gas decomposes into solid copper, CuCl (a solid), CuCl₂ (a solid), and gaseous chlorine. It is believed that the solid phases (CuClₓ) redeposit on ball to create small copper or CuClₓ particles that are in contact with or close to the copper ball, part of the porous copper film referred to above, and will be part of the ball bond as will any trapped chlorine gas. The film and particles will tend to drive the formation of a less than ideal copper ball-bond pad interface, thus having regions were no reaction between the copper ball and the aluminum bond pad take place, referred to as voided interfacial regions. These voided regions are weak and susceptible to degradation over time. One such degradation mechanism is believed to be related to chlorine trapped during wire bonding, another is chlorine contamination from the substrate in a post wire bond clean step. If the interface voids are present such that they have channels that are open to the external ambient, then external gases can get into the ball-bond pad interface. One such gas is chlorine. After wire bonding, the device is subjected to a plasma clean step. Chlorine can be generated during this step by, for example, outgassing from the substrate or the die attach adhesive. If there are interface channels then the chlorine gas can get into the interface and react with copper or the reaction product. Subsequently the device is overmolded with a polymer protective coating onto the device and bond wires. This coating will trap any gasses that are present in the ball bond-pad interface. These can then further react and eventually cause device failure.

One mechanism that might explain how the degradation occurs involves copper-chlorine reactions. It is known that copper and chlorine gas can react with two competing reactions: growing of CuClₓ solid compounds (Cu+Cl/Cl₂→CuClₓ) is dominant when the temperature is less than approximately 150° C., and etching (CuClₓ→Cu₃Cl₃+Cu+Cl₂) is dominant when the temperature is greater than approximately 150° C. During normal operation of the packaged device, the device might repeatedly experience temperatures in the range of 150-200° C., causing multiple etching/growing cycles and possibly leading to failure of the ball bond. Moreover, any cleaning of the device and substrate after bonding, such as by plasma cleaning using argon, might enhance the etching/growing reaction rates discussed above.

To address the issue of chlorine contamination and other potential contaminates that could lead to less than ideal bond wire-die pad interface formation, a purge gas is directed onto the portion of the substrate 102 having devices 104 thereon waiting for wire bonding. Referring to FIGS. 1 and 2, a pipe 130 is provided that receives an inert or low moisture content gas (purge gas), such as nitrogen or CDA, from a source that might be the same gas source as that used to supply gas to nozzle 230 (FIG. 2). The pipe 130 has nozzles or openings 132 to direct the purge gas 134 onto the substrate 102, preferably directing the purge gas parallel to the surface of the substrate. This floods the substrate to the left of the clamp 106 to flush contaminants such as chlorine from the vicinity of the substrate 102 and the devices 104 attached thereto. While it might be desirable to also provide the purge gas on the right side of the clamp 106 (gas from the nozzle 230 in FIG. 2 is presumably flooding the region 108), it is believed that there is no need for the purge gas once the ball bonds have been completed and those ball bonds are formed with no significant interface voids that also have channels open to the external ambient. Preferably, a laminar flow of the purge gas occurs over the substrate 102. Too high a gas flow will result in turbulent gas flow that might reduce the prophylactic effect of the purge gas. An exemplary minimum gas flow rate from the nozzles 132 is approximately 0.3-5 liters per minute.

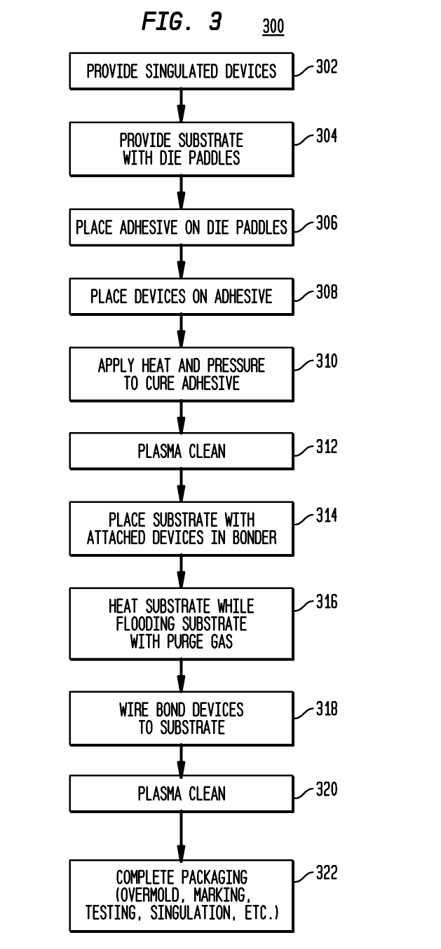

FIG. 3 is a simplified flowchart illustrating an exemplary process 300 for attaching integrated circuit devices to a substrate, wire bonding the integrated circuit devices to the substrate, and completing the packaging of the device and respective substrate. Starting with step 302, integrated circuit devices are provided (e.g., devices 104) that are singulated, i.e. separated from each other by sawing a semiconductor wafer (not shown). The devices have bond pads thereon (e.g., bond pads 114) that will receive bond wires. Then in step 304, a substrate (e.g., substrate 102) is provided that has die paddles (e.g., die paddles 202) thereon. In step 306, adhesive (e.g., adhesive 204), such as a silver-filled epoxy, is applied to the die paddles and then in step 308 individual devices are placed on the adhesive. Heat and pressure are applied to the devices and the substrate in a flowing gas atmosphere (e.g., nitrogen or CDA) to remove contaminants while the adhesive cures in step 310. In one embodiment, the temperature is typically between 100° C. and 175° C. and the cure time is approximately 30 minutes. Alternatively, the adhesive might be cured using UV light in combination with heat and pressure. Once the adhesive has cured, in step 312 the substrates are cleaned with a low power (less than 1000 watts) plasma clean typically using a low-pressure atmosphere of argon alone or a combination of argon and oxygen or argon and nitrogen. The plasma clean removes contaminants on the bond pads and substrate pads in preparation for wire bonding. Alternatively, a wet clean using, for example, diluted solution of hydrochloric acid and hydrogen peroxide, might be used to clean the bond pads and substrate pads. Then the cleaned substrate and devices are placed in the bonder (e.g., bonder 100) in step 314 and then, in accordance with one embodiment of the invention, the substrate is heated while the substrate and devices are flooded with a purge gas (e.g., purge gas 134) in step 316. In step 318 the devices are wire bonded as described above. Then the wire bonded devices and substrate are plasma cleaned in step 320 to remove contaminants and to improve adhesion of overmold compounds applied in the following step. Packaging of the wire-bonded devices is completed in step 322 by applying an overmold protection to the devices, the packages marked, and the substrate sawed to singulate the devices. Other sub-steps might be included in step 322 such as testing.

While the embodiments described here use a ball bond to attach a bond wire to a bond pad, other types of bonds might be used, such as a wedge bond.

Although the elements in the following method claims are recited in a particular sequence with corresponding labeling, unless the claim recitations otherwise imply a particular sequence for implementing some or all of those elements, those elements are not necessarily intended to be limited to being implemented in that particular sequence.

It is understood that various changes in the details, materials, and arrangements of the parts which have been described and illustrated in order to explain the nature of this invention might be made by those skilled in the art without departing from the scope of the invention as expressed in the following claims.

1. An apparatus comprising:
a heater block configured to heat a substrate and devices attached to a major surface of the substrate;
a clamp configured to press the substrate down onto the heater block and thereby isolating a region of the substrate and devices attached thereto from a remainder of the substrate and devices;
a bonder head, operable within the isolated region, configured to attach bond wires from bond pads on the devices to substrate pads on the major surface and adjacent to the device being wire bonded in the isolated region;
a gas source configured to flood a portion of the substrate and the devices attached thereto with a purge gas while the substrate and attached devices are being heated by the heater, the portion being apart from the substrate and the devices in the isolated region.

2. The apparatus of claim 1 further comprising:
a nozzle configured to flood the substrate and devices attached thereto in the isolated region during wire bonding, the gas selected from the group consisting of nitrogen, forming gas, condensed dry air, and a combination thereof.

3. The apparatus of claim 1 wherein the gas source comprises a pipe and a plurality of nozzles attached thereto for directing the purge gas onto and parallel with the major surface of the substrate.

4. The apparatus of claim 1 wherein the purge gas is selected from the group consisting of nitrogen, condensed dry air, and a combination thereof.

5. The apparatus of claim 1 wherein the bond wire comprises copper.

6. The apparatus of claim 5 wherein the bond pads comprise aluminum or copper and the substrate pads comprise copper.

7. The apparatus of claim 1 wherein the bonder head is configured to form a ball bond on the bond pads using ultrasonic vibration.

8. The apparatus of claim 1 wherein the device comprises a material selected from the group consisting of silicon, gallium arsenide, indium phosphide, and a combination thereof.

9. The apparatus of claim 8 wherein the substrate is selected from the group consisting of glass-epoxy, polytetrafluoroethylene, ceramic, silicon, glass, and a combination thereof.

10. A method comprising the steps of:
A) providing a substrate having a plurality of devices for wire bonding thereon, the substrate having a first edge, an opposing edge, and a plurality of substrate pads proximate the devices;
B) positioning a clamp proximate the first edge of the substrate;
C) lowering the clamp onto a portion of the substrate to form a region isolated from the rest of the substrate, the region having therein at least one of the devices to be wire bonded therein;
D) flooding the substrate between the region and the opposing edge with a purge gas;
E) heating the substrate;
F) wire bonding bond pads on the at least one device within the isolated region to substrate pads proximate the at least one device and within the region;
G) raising the clamp;
H) moving the substrate to position within the isolated region at least one device to be wire bonded;
wherein steps C)-H) are repeated until all the devices on the substrate are wire bonded.

11. The method of claim 10 wherein step A) comprises the steps of:
providing a substrate having a plurality of die paddles thereon;
providing a plurality of devices;
applying an adhesive to each of the die paddles;
placing a device on the adhesive on a respective one of the die paddles; and
curing the adhesive;

12. The method of claim 10 further comprising the step of:
cleaning, prior to step B), the substrate and attached devices.

13. The method of claim 12 wherein the cleaning uses a low-power plasma.

14. The method of claim 10 wherein the heating in step E) excludes that portion of the substrate having devices that have been moved out of the isolated region in step H).

15. The method of claim 10 further comprising, after step H), the step of:
plasma cleaning the substrate and wire bonded devices.

16. The method of claim 10 wherein step F) comprises the step of:
flooding the isolated region with a gas selected from the group consisting of nitrogen, forming gas, condensed dry air, and a combination thereof.

17. The method of claim 10 wherein the purge gas is selected from the group consisting of nitrogen, condensed dry air, and a combination thereof.

18. The method of claim 10 wherein each of the devices comprises a material selected from the group consisting of silicon, gallium arsenide, indium phosphide, and a combination thereof.

19. The method of claim 10 wherein the substrate is selected from the group consisting of glass-epoxy, polytetrafluoroethylene, ceramic, silicon, glass, and a combination thereof.

20. The method of claim 10 further comprising the steps of:
forming, after step H), an overmold over each of the wire bonded devices and the substrate; and
singulating the overmolded devices and substrate.

21. The method of claim 10 wherein the bond wire comprises copper.

22. The method of claim 21 wherein the bond pads comprise aluminum or copper and the substrate pads comprise copper.
